(19) United States
(12) Patent Application Publication
(10) Pub. No.: US 2014/0227820 A1
(43) Pub. Date: Aug. 14, 2014

(54) PASSIVATION LAYER REMOVAL BY DELIVERING A SPLIT LASER PULSE

(71) Applicant: Applied Materials, Inc., Santa Clara, CA (US)

(72) Inventors: Jeffrey L. FRANKLIN, Albuquerque, NM (US); Yi ZHENG, Sunnyvale, CA (US)

(73) Assignee: Applied Materials, Inc., Santa Clara, CA (US)

(21) Appl. No.: 13/763,295

(22) Filed: Feb. 8, 2013

(51) Int. Cl. H01L 31/18

(52) U.S. Cl. CPC H01L 31/18
USPC 438/57

(57) ABSTRACT

Embodiments of the present invention generally provide methods for forming features or holes in a passivation layer without damaging the underlying solar cell substrate. A source laser beam is split into a first laser beam and a second laser beam. The first laser beam is modified to have a different wavelength than the source laser beam. The second laser beam is delayed for a predetermined time, and the first and second laser beams are delivered to a surface of the substrate.

### BACKGROUND OF THE INVENTION

1. Field of the Invention

Embodiments of the present invention generally relate to an apparatus and method for laser drilling of holes in one or more layers during solar cell fabrication.

2. Description of the Related Art

Solar cells are photovoltaic devices that convert sunlight directly into electrical power. The most common solar cell material is silicon, which is in the form of single or multi-crystalline substrates, sometimes referred to as wafers. Because the amortized cost of forming silicon-based solar cells to generate electricity is higher than the cost of generating electricity using traditional methods, there has been an effort to reduce the cost required to form solar cells.

One solar cell design in widespread use today has a p/n junction formed near the front surface, or surface that receives light, which generates electron/hole pairs as light energy is absorbed in the solar cell. This conventional design has a first set of electrical contacts on the front side of the solar cell, and a second set of electrical contacts on the back side of the solar cell. In order to form the second set of electrical contacts on the back side of the solar cell, network of openings in the pattern of either holes or lines must be formed in a passivation layer that uniformly covers the back side of a solar cell substrate to allow photo generated carriers (electrons or holes) to be conducted through a conductive layer in contact with the underlying solar cell substrate.

It is common to need distributed network of contacts, either in dot or line pattern. In case of dot pattern, in excess of 100,000 contact points (i.e., holes formed in the back side passivation layer) are normally formed on a single solar cell substrate. In case of lines, in excess of 150 contact lines are formed on a single solar cell substrate. Conventional approaches to forming contact openings in the back side passivation layer of the solar cell include the use of a galvanometer system to steer a laser beam across the solar cell substrate. However, using conventional laser systems, it is difficult to remove the passivation layer cleanly without damaging the underlying solar cell bulk materials where the light is absorbed and converted to photo electron-hole pair. Specifically, the difficulty is mainly due to the fixed laser wavelength, pulse length and beam energy profile for a given laser system so that the interaction between laser beam and passivation layer and underlying solar cell bulk materials cannot be simultaneously optimized to reach the desired results of cleanly removing the passivation layer and minimizing residue materials while avoiding damaging the underlying solar cell bulk materials.

Accordingly, improved methods for forming openings in a passivation layer of a solar cell substrate are needed.

### SUMMARY OF THE INVENTION

Embodiments of the present invention generally provide methods for forming openings in a passivation layer to simultaneously optimize the passivation layer ablation and minimizing solar cell damage. A source laser beam is split into multiple beams (two or more), for example a first laser beam and a second laser beam. The first laser beam is modified to have a different wavelength than the source laser beam. The second laser beam is delayed for a predetermined time from when the first laser beam is delivered, and the first and second laser beams are delivered to a surface of the substrate. In the case of pulsed laser beam, the first of the split pulse may or may not overlap with the second split pulse. The delay between the pulses can be adjusted according to the passivation materials stack.

In one embodiment, a method for forming a feature on a substrate is disclosed. The method comprises receiving a source laser beam having a first wavelength, splitting the source laser beam to form a first laser beam and a second laser beam, modifying the first laser beam so that the first laser beam has a second wavelength, delaying the second laser beam for a predetermined time, and delivering the first and second laser beams to a surface of the substrate.

In another embodiment, a method for forming a feature on a substrate is disclosed. The method comprises receiving a source laser beam having a first wavelength, splitting the source laser beam to form a first laser beam and a second laser beam, modifying the first laser beam so that the first laser beam has a second wavelength, modifying the energy profiles of the first laser beam, and delivering the first and second laser beams to a surface of the substrate.

In another embodiment, a method for forming a feature on a substrate is disclosed. The method comprises receiving a source laser beam having a first wavelength, splitting the source laser beam to form a first laser beam and a second laser beam, modifying the first laser beam so that the first laser beam has a second wavelength, modifying the energy profiles of the first and the second laser beams, delaying the second laser beam for a predetermined time, and delivering the first and second laser beams to a surface of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a cross-sectional view of a solar cell that may be formed using apparatus and methods described herein.

FIG. 2 illustrates a schematic side view of a laser scanning module in accordance with embodiments described herein.

FIG. 3 illustrates a schematic view of a laser scanning apparatus in accordance with embodiments described herein.

FIG. 4 illustrates a schematic view of a beam stretcher assembly in accordance with embodiments described herein.

FIG. 5 illustrates a schematic diagram of energy profiles described within an embodiment contained herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally provide methods for forming openings in a passivation layer to simultaneously optimize the passivation layer ablation and minimizing solar cell damage. A source laser beam is split into multiple beams (two or more), for example a first laser beam and a second laser beam. The first laser beam is modified to have a different wavelength than the source laser beam. The second laser beam is delayed for a predetermined time from when the first laser beam is delivered, and the first and second laser beams are delivered to a surface of the substrate. In the case of pulsed laser beam, the first of the split pulse may or may not overlap with the second split pulse. The delay between the pulses can be adjusted according to the passivation materials stack.

As used herein, the term “laser drilling” generally means removal of at least a portion of material by delivering an amount of electromagnetic radiation, such as optical radiation in the form of light energy. Thus, “laser drilling” may include ablation of at least a portion of a material layer disposed on a substrate, e.g., a hole through a material layer disposed on a substrate. Further, “laser drilling” may include removal of at least a portion of substrate material, e.g., forming a non-through hole (blind hole) or lines in a substrate or a hole through a substrate.

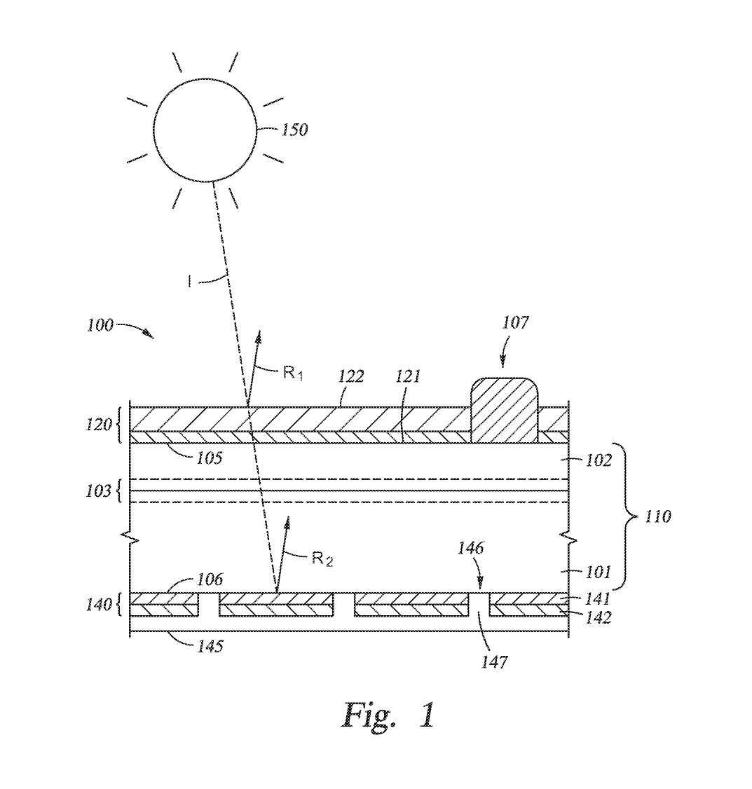

FIG. 1 illustrates a cross-sectional view of a solar cell 100 that may be formed using apparatus and methods described herein. The solar cell 100 includes a solar cell substrate 110 that has a passivation/ARC (anti-reflective coating) layer stack 120 on a front surface 105 of the solar cell substrate 110 and a rear passivation layer stack 140 on a rear surface 106 of the solar cell substrate.

In one embodiment, the solar cell substrate 110 is a silicon substrate that has a p-type dopant disposed therein to form part of the solar cell 100. In this configuration, the solar cell substrate 110 may have a p-type doped base region 101 and an n-doped emitter region 102 formed thereon. The solar cell substrate 110 also includes a p-n junction region 103 that is disposed between the base region 101 and the emitter region 102. Thus, the solar cell substrate 110 includes the region in which electron-hole pairs are generated when the solar cell 100 is illuminated by incident photons “I” from the sun 150.

The solar cell substrate 110 may include single crystal silicon, multi-crystalline silicon, or polycrystalline silicon. Alternatively, the solar cell substrate 110 may include germanium (Ge), gallium arsenide (GaAs), cadmium telluride (CdTe), cadmium sulfide (CdS), copper indium gallium selenide (GIGS), copper indium selenide (CuInSe2), gallium indium phosphide (GaInP2), or organic materials. In another embodiment, the solar cell substrate may be a heterojunction cell, such as a GaInP/GaAs/Ge or a ZnSe/GaAs/Ge substrate.

In the example shown in FIG. 1, the solar cell 100 includes a passivation/ARC layer stack 120 and a rear passivation layer stack 140 that each contains at least two or more layers of deposited material. The passivation/ARC layer stack 120 includes a first layer 121 that is in contact with the front surface 105 of the solar cell substrate 110 and a second layer 122 that is disposed on the first layer 121. The first layer 121 and the second layer 122 may each include a silicon nitride (SiN) layer, which has a desirable quantity of trapped charge and refractive index and extinction coefficient (optical properties) formed therein to effectively help bulk passivate the front surface 105 of the solar cell substrate.

In one embodiment, the rear passivation layer stack 140 includes a first backside layer 141 that is in contact with the rear surface 106 of the solar cell substrate 110 and a second backside layer 142 that is dispose on the first backside layer 141. The first backside layer 141 may include an aluminum oxide (AlₓO_{y}) layer that is between about 50 Å and about 1300 Å thick and has a desirable quantity of fixed charge formed therein to effectively passivate the rear surface 106 of the solar cell substrate 110. The second backside layer 142 may include a silicon nitride (SiN), silicon oxinitride (SiON) and/or silicon oxide (SiO₂) layer that is between about 300 Å and about 3000 Å thick. Both the first backside layer 141 and the second backside layer 142 have a desirable quantity of fixed charge formed therein to effectively help passivate the rear surface 106 of the solar cell substrate 110. The passivation/ARC layer stack 120 and the rear passivation layer stack 140 minimize front surface reflection R₁ and maximize rear surface reflection R₂ in the solar cell 100, as shown in FIG. 1, which improves efficiency of the solar cell 100.

The solar cell 100 further includes front side electrical contacts 107 extending through the passivation/ARC layer stack 120 and contacting the front surface 105 of the solar cell substrate 110. The solar cell 100 also includes a conductive layer 145 that forms rear side electrical contacts 146 that electrically contact the rear surface 106 of the solar cell substrate 110 through holes 147 formed in the rear passivation layer stack 140. The conductive layer 145 and the front side electrical contacts 107 may include a metal, such as aluminum (Al), silver (Ag), tin (Sn), cobalt (Co), nickel (Ni), zinc (Zn), lead (Pb), tungsten (W), titanium (Ti), tantalum (Ta), nickel vanadium (NiV), or other similar materials, and combinations thereof.

In forming the rear side electrical contacts 146, a number of through holes 147 or lines (not shown) must be formed in the rear passivation layer stack 140 without damaging the rear surface 106 of the solar cell substrate 110. In order to minimize the resistance losses in the solar cell 100 a high density of holes (e.g., between 0.5 and 5 holes per square millimeter) or lines (e.g. with spacing between 0.3 to 2.5 millimeter) is required. Embodiments of the present invention provide methods of forming the holes 147 in the rear passivation layer stack 140 without damaging the rear surface 106 of the solar cell substrate 110.

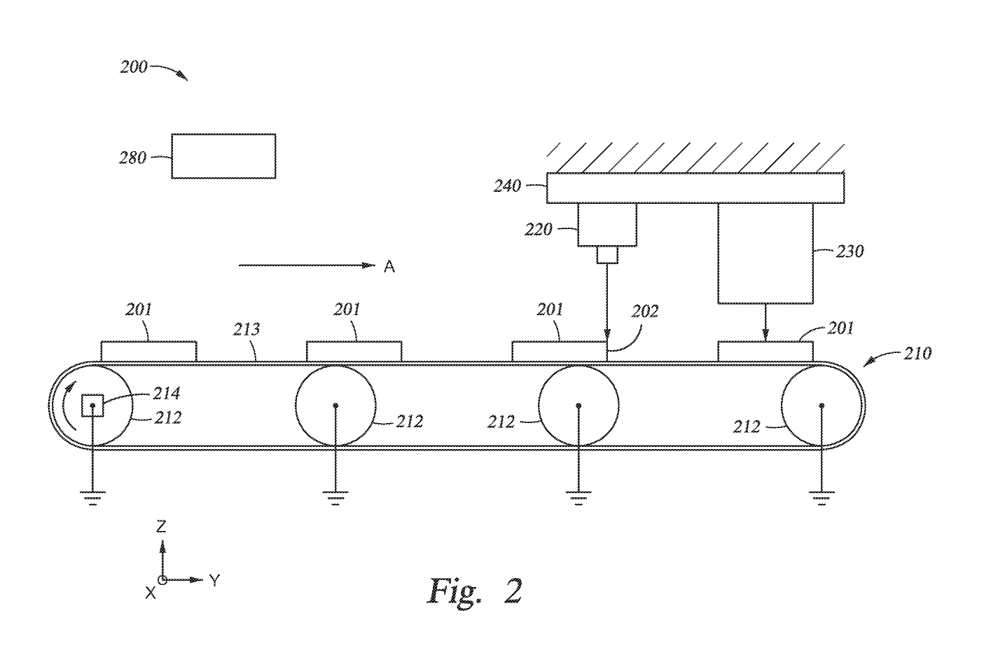

FIG. 2 illustrates a schematic side view of a laser scanning module 200 for scanning rows of features or holes in one or more layers of a substrate 201 in accordance with embodiments of the present invention. The laser scanning module 200 includes a substrate positioning system 210, one or more substrate position sensors 220, the laser scanning apparatus 230 and a system controller 280.

The system controller 280 is adapted to control the various components of the laser scanning module 200. The system controller 280 generally includes a central processing unit (CPU) (not shown), memory (not shown), and support circuits (not shown). The CPU may be one of any form of computer processor used in industrial settings for controlling system hardware and processes. The memory is connected to the CPU and may be one or more of a readily available memory, such as random access memory (RAM), read only memory (ROM), floppy disk, hard disk, or any other form of digital storage, local or remote. Software instructions and data can be coded and stored within the memory for instruction the CPU. The support circuits are also connected to the CPU for supporting the processor in a conventional manner. The support circuits may include cache, power supplies, clock circuits, input/output circuitry subsystems, and the like. A program (instructions) readable by the system controller 280 includes code to perform tasks relating to monitoring, executing, and controlling the movement, support, and positioning of the substrates 201 along with various process recipe tasks to be performed in the laser scanning module 200. Thus, the system controller 280 is used to control the functions of the substrate positioning system 210, the one or more substrate position sensors 220, and the laser scanning apparatus 230.

In one embodiment, the substrate positioning system 210 is a linear conveyor system that includes support rollers 212, that support and drive a continuous transport belt 213 of material configured to support and transport a line of the substrates 201 through the laser scanning module 200. The support rollers 212 may be driven by a mechanical drive 214, such as a motor/chain drive, and may be configured to transport the transport belt 213 at a linear speed of between about 100 and about 300 mm/s. The mechanical drive 214 may be an electric motor (e.g., AC or DC servo motor). The transport belt 213 may be made of a polymeric, stainless steel, or aluminum. In one embodiment, the substrates 201 are transported by the substrate positioning system 210 along a path indicated by arrow “A”.

The substrate positioning system 210 is configured to sequentially transport a line of the substrates 201 (i.e., in the Y-direction) beneath a gantry 240, which supports the one or more position sensors 220 and the laser scanning apparatus 230. The one or more position sensors 220 are configured and positioned to detect a leading edge 202 of the substrate 201 as it is transported by the substrate positioning system 210 and send corresponding signals to the system controller 280. The signals from the one or more position sensors 220 are used by the system controller 280 to determine and coordinate the timing of the delivery of one or more electromagnetic radiation pulses from the laser scanning apparatus 230 to a surface of each of the substrates 201.

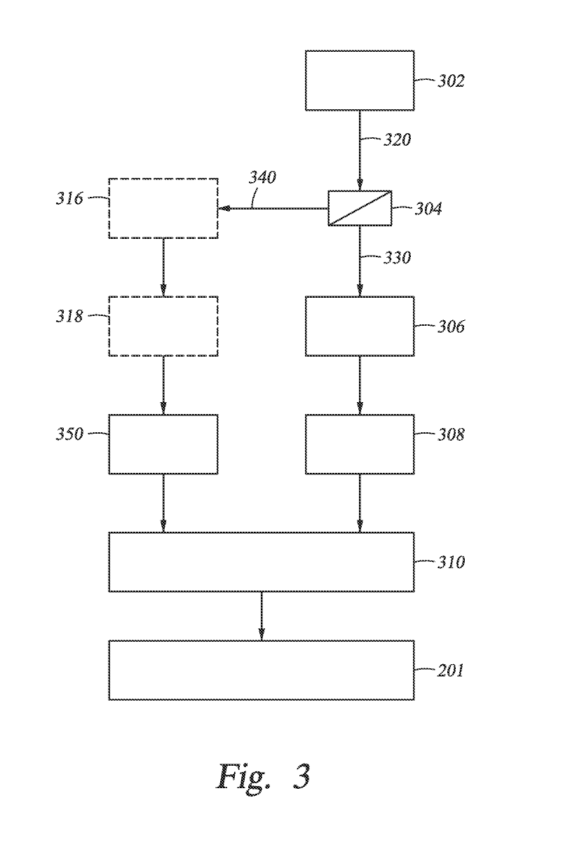

FIG. 3 illustrates a schematic view of the laser scanning apparatus 230 in accordance with embodiments described herein. The laser scanning apparatus 230 comprises an energy source 302, a beam splitter 304, one or more wavelength converters 306, a beam stretcher assembly 308, and a relay optics assembly 310. The energy source 302 emits light or electromagnetic radiation, such as a source laser beam 320 through a process of optical amplification based on stimulated emission of photons. The source laser beam 320 may be a Nd:YAG, Nd:YVO₄, crystalline disk, fiber-Diode and other similar radiation emitting sources that can provide and emit a continuous wave or pulses of radiation at a wavelength between about 238 nanometers (nm) and about 1540 nm. In one embodiment, the source laser beam 320 has a wavelength between about 255 nm and about 1064 nm. In one embodiment, the source laser beam 320 is an infrared laser having a wavelength of about 1064 nm.

In one embodiment, the energy source 302 includes a switch (not shown), such as a shutter, capable of being opened and closed in 1 microsecond (μs) or less. The shutter generates pulses by interrupting a continuous beam of electromagnetic energy directed toward a substrate. In one embodiment, the energy source 302 produces a pulse at a pulse width of from about 1 femtoseconds (fs) to about 1.5 microseconds (μs) having a total energy of from about 10 pJ/pulse to about 6 mJ/pulse.

The source laser beam 320 is split by the beam splitter 304 to form two laser beams 330, 340. The two laser beams 330, 340 have the same wavelength as the source laser beam 320. In one embodiment, the laser beam 330 may be utilized to perform laser drilling on the passivation layer deposited on the substrate 201. In order to do so, the frequency of the laser beam 330 may be increased by employing one or more wavelength converters 306. The wavelength converter 306 may include a non-linear crystal, such as KTP (potassium titanium oxide phosphate, KTiOPO₄), BBO (beta barium borate, beta BaB₂O₄), and LB (lithium triborate, LiB₃O₅) that are able to adjust the frequency of the optical energy delivered therethrough. The laser beam 330 may have a wavelength ranging from about 266 nm to about 800 nm as modified by one or more wavelength converters 306. In one example, the laser beam 330 has a wavelength of about 532 nm after passing through the wavelength converter 306. In another example, the laser beam 330 has a wave length that is less than the originally delivered wavelength after passing through the wavelength converter 306. Therefore, in one example, the source laser beam 320 has a wavelength that is between about 238 nm and about 1540 nm and the laser beam 330 has a second wavelength that is between about 238 nm and about 800 nm. In another example, the source laser beam 320 has a wavelength that is between about 800 nm and about 1540 nm and the laser beam 330 has a second wavelength that is between about 266 nm and about 800 nm. In yet another example, the source laser beam 320 has a wavelength that is greater than about 800 nm and the laser beam 330 has a second wavelength that is less than about 800 nm.

The laser beam 330 would then pass through a beam stretcher assembly 308 to optimize the profile of the delivered optical energy as a function of time that is delivered to the surface of the substrate 201(details discussed below). Once the energy profile is optimized, the laser beam 330 would pass through the relay optics assembly 310 and strike the surface of the substrate 201 to perform laser drilling on the passivation layer deposited on a surface of the substrate 201. It is believed that a laser beam 330 having a wavelength between about 266 nm and about 800 nm is capable to removing a portion of a typical passivation layer found in the passivation layer stacks 120 and 140, which are discussed above. For example, a laser beam having a wavelength of 532 nm and an energy density of 50 pJ/pulse would remove portions of the first and second backside layers 141, 142 of the passivation stack 140 having a total thickness of 2000 Å. However, due to the transmission of the laser energy through the passivation layer and absorption of the laser energy in the underlying substrate, it is common for the delivered energy to cause some damage to the surface region of the underlying substrate usually in the form of point defects or dislocations or even melting and micro-cracking.

In some embodiments, the laser beam 340 is utilized to repair the damages in the underlying substrate provided by the delivery of the laser beam 330, by “annealing” the affected region of the substrate. One skilled in the art would appreciate that annealing may include the process of delivering an amount of optical energy to the substrate to provide enough energy to cause the reorganization of the atoms in the affected region to cause the removal of at least a portion of the defects formed therein to restore the equilibrium state. The annealing process may also include the delivery of enough optical energy to melt and recrystallize the affected region of the substrate, thus, repairing the damages in the region of the substrate as a result to recover, at least partially, carrier lifetime and hence a solar cell of higher conversion efficiency.

In some embodiments, the laser beam 340 has the same wavelength as the source laser beam 320. In one example, the laser beam 340 has a wavelength of about 1064 nm. In one embodiment, the laser beam 340 may be unmodified before reaching the surface of the substrate 201 to perform the annealing process. In one embodiment, since the laser beam 340 is utilized to repair the damages caused by the laser beam 330, the laser beam 340 is recombined with the laser beam 330 to strike the same location on the substrate 201. In this configuration, the laser beam 340 may go through a delay assembly 350 so that the laser beam 340 strikes the substrate 201 a period of time after the laser beam 330 is delivered to the surface, such as 50 nanoseconds (ns) after the laser beam 330 strikes the substrate 201. For the typical passivation layers discussed above, it typically takes at least 50 ns for the laser drilling of the laser beam 330 to take effect. Thus, in one embodiment, the laser beam 340 should strike the substrate 201 at least 50 ns after the laser drilling performed by the laser beam 330. On the other hand, the delay may be less than 5 milliseconds (ms). In configuration where the substrate 201 is disposed on a moving transport belt 213, if the delay is too long, the laser beam 340 may completely miss the hole drilled by the laser beam 330. Because of the moving substrate 201 and scanning portions of the optics to the laser, any significant delay in time can cause the laser beam 340 striking the substrate 201 to occur at a different location than the hole drilled by the laser beam 330. However, it is believed that the repair of the underlying substrate of the substrate 201 with the laser beam 340 may be sufficient when the laser beam 340 covers about 70% of the hole drilled by the laser beam 330. This offset in location by split pulses will not be a concern for line pattern at all.

In another embodiment, the beam 340 and 330 (in FIG. 3) can be modified in terms of wavelength and energy profile so as to be optimized for ablation of layers 142 and 141 respectively. For example, beam 340 can be of wavelength 532 nm that is suitable for ablating a typical top layer 142 of SiNx and beam 330 can be modified to be 355 nm (UV) to ablate the layer 141. Since UV has very high absorption coefficient and thus shallow penetration depth in the underlying substrate, most of the laser energy is absorbed in layer 141 and little damage is exerted in the underlying substrate.

In some embodiments, the laser beam 340 is modified before reaching the substrate 201. In one embodiment, the laser beam 340 passes through a delay assembly 350 and then gets recombined with the laser beam 330. In one configuration, the recombined laser beam, with the laser beam 330 50 ns ahead of the laser beam 340, passes through the wavelength converter 306, the beam stretcher assembly 308, and the relay optics assembly 310. The laser beam 330 performs laser drilling on the passivation layer deposited on the substrate 201, and the laser beam 340 anneals the underlying substrate inside the hole 50 ns after the drilling of the hole by the laser beam 330.

In another embodiment, prior to passing through a delay assembly 350, the laser beam 340 passes through a different wavelength converter 316, and/or a different beam stretcher assembly 318. Then, the laser beam 340 gets recombined with the laser beam 330 at the relay optics assembly 310 and performs an annealing process on the underlying substrate inside the hole at least 50 ns after the drilling of the hole by the laser beam 330. Yet in another embodiment, the beam stretcher assembly 318 causes enough delay of the laser beam 340, so a delay assembly 350 is not needed.

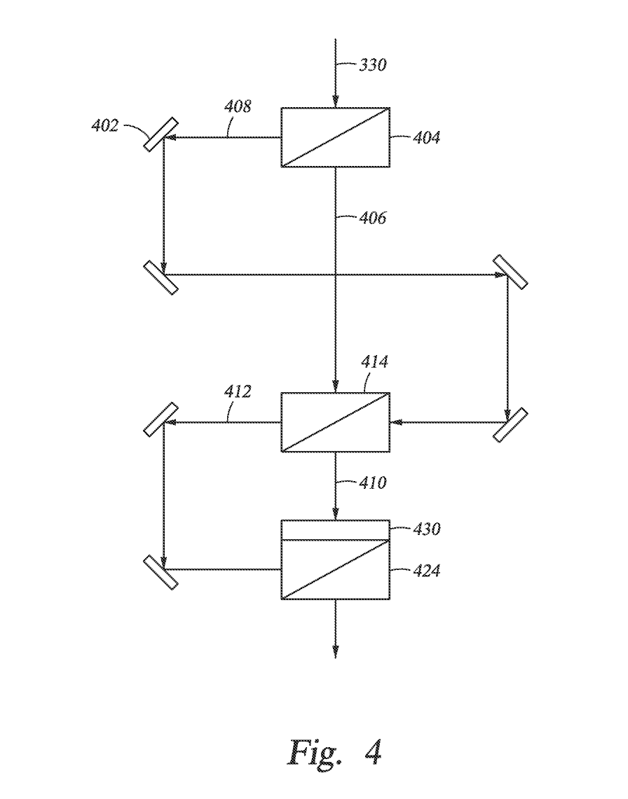

FIG. 4 illustrates a schematic view of the beam stretcher assembly 308 in accordance with embodiments described herein. Most conventional lasers are not able to deliver a beam that has a desirable profile, and thus the laser beam delivered from the energy source 302 to the substrate 201 should be adjusted to reduce damage to the substrate and/or optimize the annealing process. As shown in FIG. 4, the beam stretcher assembly 308 may comprise a plurality of mirrors 402 (e.g., 6 mirrors are shown) and a plurality of beam splitters (e.g., reference numerals 404, 414, and 424) that are used to delay portions of the laser beam 330 to provide a composite beam that has a desirable beam characteristics (e.g., beam width and beam profile). The number of mirrors and beam splitters may vary based on the desired energy profile.

In one embodiment, the laser beam 330 is split into two beams 406, 408, after passing through the first beam splitter 404. In general, by adjusting the difference in path length between the first beam 406 and the second beam 408, a delay of about 1.02 ns per foot can be realized. Next, the beam 406 delivered to the second beam splitter 414 is split into another two beams 410, 412. The process of splitting and delaying each of the beams continues as each of the beams strike subsequent beam splitters and mirrors until the beams are all recombined in the final beam splitter 424 that is adapted to primarily deliver energy to the next component in the laser scanning apparatus 230. The final beam splitter 424 may be a polarizing beam splitter that adjusts the polarization of the energy in the beams received from the delaying regions or from the prior beam splitter so that the recombined beams can be directed in a desired direction. In one embodiment, a waveplate 430 is positioned before the final beam splitter 424 to adjust the polarization of energy in the beams. Without the adjustment to the polarization, a portion of the beam 412 would be reflected by the final beam splitter 424 and not get recombined with other beams. The beam stretcher assembly 308 is not limited to the configuration shown in FIG. 4. Various configurations may be utilized to produce desired energy profile.

As mentioned above, the laser beam 340 may also pass through the same beam stretcher assembly 308 after recombining with the laser beam 330. In other embodiments, the laser beam 340 may pass through the beam stretcher assembly 318. The beam stretcher assembly 318 may or may not have the same configuration as the beam stretcher assembly 308.

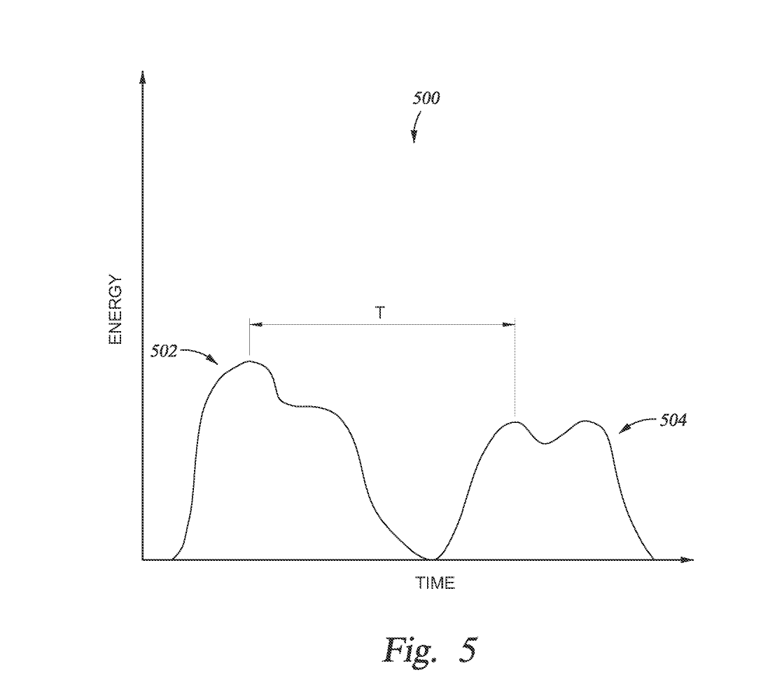

FIG. 5 illustrates a schematic diagram 500 of energy profile described within an embodiment contained herein. An unmodified laser beam (i.e. a laser beam without passing through the beam stretcher assembly 308), typically has an energy profile showing a Gaussian peak. However, the laser beam may not be ideal for drilling, annealing, or both. Thus, the beam stretcher assembly 308 is utilized to modify the energy profile of laser beams so that the beams are optimized for drilling, annealing, or both. The mirrors and the beam splitters in the beam stretcher assembly 308 split one beam pulse into multiple sub-beam pulses, delay one or more beams, and recombine the beams. As a result, the energy profile is no longer the original shape of the laser beam (e.g., Gaussian) due to the super-position of the sub-beam pulses in time. In this way, the shape of the each laser beam pulse (e.g., laser beams 330 and/or 340) can be tailored by the delivery of each laser beam pulse through at least a portion of one or more desirably configured beam stretching assemblies. The schematic diagram 500 graphically illustrates a plot of two laser beams 330, 340 after passing through one or more beam stretcher assemblies, so that they are delivered a distance in time apart, or period “T”, to form a hole in the passivation layer on the substrate 201 and then to anneal the damaged underlying substrate within the hole. Curve 502 represents the energy delivered to the substrate 201 by the laser beam 330 and curve 504 represents the energy delivered to the substrate 201 by the laser beam 340. The time period “T” may be between about 50 ns to about 5 ms. In one embodiment, the time period “T” is about 50 ns. As a result of passing through the beam stretcher assembly 308 and 318, the energy profiles of the laser beams 330 and 340 both demonstrate a non-Gaussian distribution, as represented by curves 502 and 504. One will note that the initial pulse shape of laser beam 330 and laser beam 340 may be a Gaussian shape before they are modified and delivered to the substrate surface. The energy profiles (e.g., time varying energy level or pulse shape) of beams 330 and 340 each having different wavelengths, may be modified to any shape in order to optimize laser drilling and annealing.

In some embodiments, as discussed above, a source laser beam is split into a first laser beam and a second laser beam both having the same wavelength as the source laser beam. The wavelength of the first laser beam is modified so the first laser beam may perform laser drilling on a passivation layer deposited on a substrate. The second laser beam is delayed by a predetermined time and is later recombined with the first laser beam. The second laser beam performs an annealing process inside the feature formed by the first laser beam to repair the damages in the underlying substrate caused by the first laser beam.

While the foregoing is directed to embodiments of the present invention, other and further embodiments of the invention may be devised without departing from the basic scope thereof, and the scope thereof is determined by the claims that follow.

1. A method for forming a feature on a substrate, comprising:
receiving a source laser beam having a first wavelength;
splitting the source laser beam to form a first laser beam and a second laser beam;
modifying the first laser beam so that the first laser beam has a second wavelength;
delaying the second laser beam for a predetermined time; and
delivering the first and second laser beams to a surface of the substrate.

2. The method of claim 1, wherein the first wavelength is greater than the second wavelength.

3. The method of claim 2, wherein the first wavelength is between about 800 nm and about 1540 nm and the second wavelength is between about 266 nm and about 800 nm.

4. The method of claim 1, wherein the modifying the first laser beam comprises passing the first laser beam through one or more wavelength converters.

5. The method of claim 1, wherein the predetermined time is between about 50 ns and about 5 ms.

6. The method of claim 1, further comprising recombining the first and the second laser beams.

7. The method of claim 1, further comprising modifying the second laser beam so that the second laser beam has a third wavelength.

8. A method for forming a feature on a substrate, comprising:
receiving a source laser beam having a first wavelength;
splitting the source laser beam to form a first laser beam and a second laser beam;
modifying the first laser beam so that the first laser beam has a second wavelength;
modifying the energy profiles of the first and the second laser beams; and
delivering the first and second laser beams to a surface of the substrate.

9. The method of claim 8, wherein the first wavelength is greater than the second wavelength.

10. The method of claim 9, wherein the first wavelength is between about 800 nm and about 1540 nm and the second wavelength is between about 266 nm and about 800 nm.

11. The method of claim 8, wherein the modifying the first laser beam comprises passing the first laser beam through one or more wavelength converters.

12. The method of claim 8, wherein the predetermined time is between about 50 ns and about 5 ms.

13. The method of claim 8, further comprising recombining the first and the second laser beams.

14. The method of claim 8, further comprising modifying the second laser beam so that the second laser beam has a third wavelength.

15. A method for forming a feature on a substrate, comprising:
receiving a source laser beam having a first wavelength;
splitting the source laser beam to form a first laser beam and a second laser beam;
modifying the first laser beam so that the first laser beam has a second wavelength;
modifying the energy profiles of the first and the second laser beams;
delaying the second laser beam for a predetermined time; and
delivering the first and second laser beams to a surface of the substrate.

16. The method of claim 15, wherein the first wavelength is greater than the second wavelength.

17. The method of claim 16, wherein the first wavelength is between about 800 nm and about 1540 nm and the second wavelength is between about 266 nm and about 800 nm.

18. The method of claim 15, wherein the predetermined time is between about 50 ns and about 5 ms.

19. The method of claim 15, further comprising recombining the first and the second laser beams.

20. The method of claim 15, further comprising modifying the second laser beam so that the second laser beam has a third wavelength.
